(19) United States
(12) Patent Application Publication
(10) Pub. No.: US 2026/0372008 A1
(43) Pub. Date: Nov. 19, 2026

(54) MEMBER FOR SEMICONDUCTOR MANUFACTURING EQUIPMENT

(71) Applicant: NGK Corporation, Nagoya-shi (JP)

(72) Inventors: Shingo AMANO, Cupertino, CA (US); Yohei KAJIURA, Nagoya-shi (JP); Naoki TSUZUKI, Toyoake-shi (JP); Keita IKEGAMI, Nagoya-shi (JP)

(21) Appl. No.: 19/725,651

(22) Filed: Jun. 30, 2026

Related U.S. Application Data
(63) Continuation of application No. PCT/JP2025/036404, filed on Oct. 15, 2025.

(30) Foreign Application Priority Data
Dec. 2, 2024 (JP) 2024-209764

(51) Int. Cl. H10P 72/72; H01J 37/32

(52) U.S. Cl. CPC H10P 72/722; H01J 37/32724; H01J 2237/2007

(57) ABSTRACT

A member for a semiconductor manufacturing equipment including a plurality of heater electrodes and one or more jumper electrode layers, wherein when the plurality of heater electrodes are viewed in a virtual plan view, 90% or more of a length of the heater line of at least one heater electrode of the plurality of heater electrodes is composed of a plurality of straight line portions within an angle range of 20°or less, and each of the jumper electrode layers is composed of a plurality of planar jumper electrodes electrically isolated by a linearly extending insulator, and the linearly extending insulator does not linearly overlap any of the plurality of straight line portions of the heater line of the at least one heater electrode in a vertical direction.

### CROSS REFERENCE TO RELATED APPLICATIONS

This application is a continuation application of PCT/JP2025/36404 filed on Oct. 15, 2025, which claims the benefit of priority of Japanese Patent Application No. 2024-209764 filed on Dec. 2, 2024, the entire contents of which are incorporated herein by reference.

### FIELD OF THE INVENTION

The present invention is related to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like, and generally, they have the function of chucking a wafer using electrostatic force by applying electrical power for electrostatic chucking to an internal electrode.

There are a wide variety of processes for wafers, such as etching and CVD, and the optimum wafer temperature distribution differs depending on the type of process. for this reason, a member for a semiconductor manufacturing equipment is required to have the ability to control the temperature distribution of the wafer. To meet such demands, a member for a semiconductor manufacturing equipment with a multi-zone heater is known, which comprises a ceramic substrate incorporating a plurality of heater electrodes.

Japanese Patent Application Publication No. 2020-129633 (Patent Literature 1) discloses that a heater electrode is formed by screen-printing a metallizing paste on a ceramic green sheet and then firing it. The heater electrode is electrically connected to a driver electrode for power supply.

This literature discloses that “During this screen printing, the thickness of the applied metallizing paste is likely to vary depending on the relationship between the extending direction of the heater line portion 510 of the heater electrode 500 and the moving direction of the squeegee. For example, in a portion where the extending direction of the heater line portion 510 and the moving direction of the squeegee are substantially orthogonal (or nearly so), the thickness of the applied metallizing paste tends to be thinner compared with other portions. If there is variation in the thickness of the applied metallizing paste, there will be variation in the amount of heat generated at each position on the heater line portion 510 of the produced heater electrode 500, which will in turn impair the controllability of the temperature distribution on the attraction surface S1, which is undesirable.”

The electrostatic chuck heater described in Japanese U.S. Pat. No. 6,397,588 (Patent Literature 2) includes an electrostatic chuck, a sheet heater, and a support base. The sheet heater is described as a disk-shaped member in which a correction heater electrode, a jumper line, a ground electrode, and a reference heater electrode are incorporated in a heat-resistant resin sheet. The correction heater electrodes are wired in a single stroke across the entire zone from one end to the other end. Further, referring to FIG. 2 of the literature, a jumper line is arranged in a zigzag pattern below the correction heater electrode which extends in a zigzag pattern.

### PRIOR ART

### Patent Literature

[Patent Literature 1] Japanese Patent Application Publication No. 2020-129633
[Patent Literature 2] Japanese U.S. Pat. No. 6,397,588

### SUMMARY OF THE INVENTION

In a member for a semiconductor manufacturing equipment with multi-zone heaters, heater electrodes are often formed by screen printing. As suggested in Patent Literature 1, if there is a difference between the printing direction and the extending direction of the heater lines constituting the heater electrodes, the printing thickness will vary, and therefore it is preferable to align the printing direction with the extending direction of the heater lines.

On the other hand, in a member for a semiconductor manufacturing equipment with a multi-zone heater, it is significant to provide a driver electrode (or jumper line) for supplying power to the heater electrode. However, Patent Literature 1 does not describe the specific structure of the driver electrode. Furthermore, in Patent Literature 2, the extending direction of the linear gaps between the jumper lines often coincides with the extending direction of the heater lines that constitute the correction heater electrode. Therefore, a linearly overlapping portion in a vertical direction arises between the extending direction of the linear gap between the jumper lines and the extending direction of the heater line.

According to the results of the study by the present inventors, when the heater line extends biasedly in a specific direction, if the extending direction of the linear gap between the jumper lines and the extending direction of the heater line overlap linearly in the vertical direction as in Patent Document 2, it has been found that cracks are likely to occur along that direction when shrinkage occurs during firing of the production process.

In view of the above circumstances, an object of one embodiment of the present invention is to provide a member for a semiconductor manufacturing equipment that comprises a plurality of heater electrodes that are zoned, in which the occurrence of cracks is suppressed.

As a result of extensive research aimed at solving the above problems, the inventors have created the present invention, which is exemplified as below.

### Aspect 1

A member for a semiconductor manufacturing equipment comprising a ceramic substrate, the ceramic substrate comprising:
an upper surface on which a wafer is to be placed;
a terminal-dense portion in which a plurality of terminals are arranged within a single section;
a plurality of heater electrodes that are zoned; and
one or more jumper electrode layers disposed between and electrically connected to the plurality of heater electrodes and each terminal of the terminal-dense portion;
wherein each of the plurality of heater electrodes comprises a heater line extending in a direction parallel to the upper surface of the ceramic substrate, and when the plurality of heater electrodes are viewed in a virtual plan view, 90% or more of a length of the heater line of at least one heater electrode of the plurality of heater electrodes is composed of a plurality of straight line portions within an angle range of 20° or less; and
wherein each of the jumper electrode layers is composed of a plurality of planar jumper electrodes electrically isolated by a linearly extending insulator, and the linearly extending insulator does not linearly overlap any of the plurality of straight line portions of the heater line of the at least one heater electrode in a vertical direction.

### Aspect 2

The member for a semiconductor manufacturing equipment according to aspect 1, wherein when the plurality of heater electrodes are viewed in a virtual plan view, 90% or more of a total length of all the heater lines of the plurality of heater electrodes is composed of a plurality of straight line portions within an angle range of 20° or less, and the linearly extending insulator does not linearly overlap any of the plurality of straight line portions of any of the heater lines in the vertical direction.

### Aspect 3

The member for a semiconductor manufacturing equipment according to aspect 1 or 2, wherein each of the plurality of heater electrodes satisfies the following Formula 1 with the planar jumper electrode electrically connected to the heater electrode:

A₂/A₁≥10 . . . Formula 1

(In which, A₁ represents an average cross-sectional area of the heater electrode in a cross section orthogonal to a direction of current flow, and A₂ represents an average cross-sectional area of the planar jumper electrode in a cross section orthogonal to the direction of current flow.)

### Aspect 4

The member for a semiconductor manufacturing equipment according to any one of aspects 1 to 3, wherein each of the plurality of terminals arranged in the terminal-dense portion is electrically connected to a predetermined planar jumper electrode through a first via extending in the vertical direction; and
each of the plurality of heater electrodes satisfies the following Formula 2 with the first via electrically connected to the heater electrode through the predetermined planar jumper electrode:

A₃/A₁≥5 . . . Formula 2

(In which, A₁ represents an average cross-sectional area of the heater electrode in a cross section orthogonal to a direction of current flow, and A₃ represents an average cross-sectional area of the first via in a cross section orthogonal to the direction of current flow.)

### Aspect 5

The member for a semiconductor manufacturing equipment according to any one of aspects 1 to 4, wherein each of the plurality of planar jumper electrodes is electrically connected to a predetermined heater electrode selected from the plurality of heater electrodes through a second via extending in the vertical direction; and
each of the heater electrodes satisfies the following Formula 3 with the second via electrically connected to the heater electrode:

A₄/A₁≥5 . . . Formula 3

(In which, A₁ represents an average cross-sectional area of the heater electrode in a cross section orthogonal to a direction of current flow, and A₄ represents an average cross-sectional area of the second via in a cross section orthogonal to the direction of current flow.)

### Aspect 6

The member for a semiconductor manufacturing equipment according to any one of aspects 1 to 5, wherein the ceramic substrate comprises 10 or more heater electrodes that are zoned.

### Aspect 7

The member for a semiconductor manufacturing equipment according to any one of aspects 1 to 6, wherein the ceramic substrate further comprises an electrostatic chuck electrode.

### Aspect 8

The member for a semiconductor manufacturing equipment according to any one of aspects 1 to 7, wherein the ceramic substrate comprises a ceramic containing 90% by mass or more of alumina.

### Aspect 9

The member for a semiconductor manufacturing equipment according to any one of aspects 1 to 8, wherein the heater electrode comprises one or more elements selected from W, Mo, and Ru.

### Aspect 10

The member for a semiconductor manufacturing equipment according to aspect 4, or any one of aspects 5 to 9 dependent on aspect 4, wherein the first via comprises one or more elements selected from W, Mo, and Ru.

### Aspect 11

The member for a semiconductor manufacturing equipment according to aspect 5, or any one of aspects 6 to 9 dependent on aspect 5, wherein the second via comprises one or more elements selected from W, Mo, and Ru.

### Aspect 12

The member for a semiconductor manufacturing equipment according to any one of aspects 1 to 11, wherein when the plurality of heater electrodes are viewed in a virtual plan view, the heater line of at least one of the plurality of heater electrodes extends linearly from one end to the other end such that the following portions repeatedly appear:
a first straight portion extending in a first direction;
a second straight portion connected to the first straight portion and extending in a second direction perpendicular to the first direction;
a third straight portion connected to the second straight portion and extending in a direction opposite to the first direction;
a fourth straight portion connected to the third straight portion and extending in the second direction perpendicular to the first direction; and
the first straight portion connected to the fourth straight portion and extending in the first direction.

### Aspect 13

The member for a semiconductor manufacturing equipment according to aspect 12, wherein a straight-line distance from the one end to the other end of the heater line is 5 mm or more.

According to the member for a semiconductor manufacturing equipment in one embodiment of the present invention, the occurrence of cracks during the manufacturing process is suppressed. Therefore, the semiconductor manufacturing equipment member can be produced with an improved yield.

### BRIEF DESCRIPTION OF THE DRAWINGS

FIG. 1 is a schematic vertical cross-sectional view of a member for a semiconductor manufacturing equipment according to one embodiment of the present invention (a cross-sectional view taken along a plane including the central axis of the member for a semiconductor manufacturing equipment).

FIG. 2 is a schematic partial enlarged view of the area surrounded by the frame in FIG. 1.

FIG. 3 shows a schematic planar structure of a plurality of heater electrodes as viewed in a virtual plan view of a member for a semiconductor manufacturing equipment according to one embodiment of the present invention, along with a partial enlarged view.

FIG. 4 shows a schematic planar structure of three jumper electrode layers located at the same height as viewed in a virtual plan view of a member for a semiconductor manufacturing equipment according to one embodiment of the present invention, along with a partial enlarged view.

FIG. 5 schematically shows example shapes of a plurality of planar jumper electrodes constituting each of the first to fifth jumper electrode layers and an example shape of a common jumper when the upper surface, which is the wafer placement surface of the ceramic substrate, is circular, the number of terminal-dense portions is three, and the number of jumper electrode layers is five.

FIG. 6 is a schematic plan view of each of the first to third jumper electrode layers.

FIG. 7 is a schematic view of the five jumper electrode layers shown in FIG. 5 as viewed virtually from above.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with the upper surface on which a wafer is to be placed facing upward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

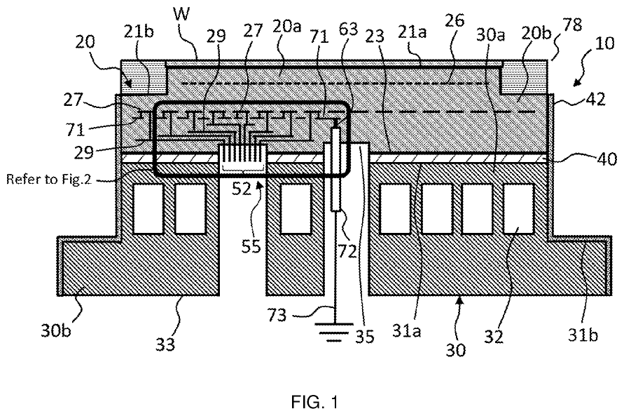

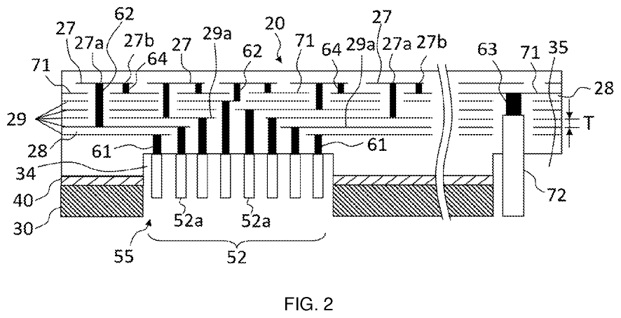

Referring to FIGS. 1 and 2, a member for a semiconductor manufacturing equipment 10 according to one embodiment of the present invention can be used when performing processes such as CVD and etching on a wafer W using plasma, and can be fixed to a mounting plate (not shown) provided inside a semiconductor process chamber. The member for a semiconductor manufacturing equipment 10 comprises a ceramic substrate 20 and a base plate 30 located on the lower surface 23 side of the ceramic substrate 20 and incorporating a refrigerant flow path 32. The ceramic substrate 20 and the base plate 30 can be bonded together by, for example, a bonding layer 40.

### 1-1. Ceramic Substrate

The ceramic substrate 20 according to one embodiment of the present invention has:
an upper surface 21a on which a wafer W is to be placed;
a terminal-dense portion 52 in which a plurality of terminals 52a are arranged within a single section 55;
a plurality of heater electrodes 27 that are zoned; and
one or more jumper electrode layers 29 disposed between and electrically connected to the plurality of heater electrodes 27 and each terminal 52a of the terminal-dense portion 52;

More specifically, the ceramic substrate 20 according to one embodiment of the present invention comprises a central portion 20a having a circular upper surface 21a in a planar view, and an outer peripheral portion 20b having an annular upper surface 21b in a planar view on the outer periphery of the central portion 20a. A wafer W can be placed on the upper surface 21a, and a focus ring 78 can be placed on the upper surface 21b. The ceramic substrate 20 is made of a ceramic material such as alumina or aluminum nitride. In a preferred embodiment, the ceramic constituting the ceramic substrate 20 contains 90% by mass or more of alumina. The upper surface 21b of the outer peripheral portion 20b is one step lower than the upper surface 21a of the central portion 20a. The lower surfaces 23 of the central portion 20a and the outer peripheral portion 20b may be flush with each other. The ceramic substrate 20 may have a central portion 20a but no outer peripheral portion 20b, that is, may not have the upper surface 21b that is one step lower.

In the embodiment shown in FIG. 1, the focus ring 78 and the upper surface of the wafer W are flush with each other, but the upper surface of the focus ring 78 may be located higher than the wafer. In the embodiment shown in FIG. 1, the outer diameter of the focus ring 78 and the outer diameter of the outer peripheral portion 20b of the ceramic substrate 20 are the same, but the two outer diameters do not have to be the same.

The upper surface 21a on which the wafer W is to be placed may be provided with a plurality of small protrusions (not shown). In addition, a seal band (not shown) may be formed along the outer edge of the upper surface 21a. In this case, the wafer W may be supported by the top surface of the seal band and the top surfaces of the small protrusions.

The central portion 20a of the ceramic substrate 20 may have a diameter of 190 to 450 mm and a thickness of 1 to 20 mm, for example. In addition, the central portion 20a of the ceramic substrate 20 may incorporate an electrostatic chuck electrode 26 on the side closer to the upper surface 21a. The electrostatic chuck electrode 26 can be made of a material containing, for example, W, Mo, WC, MoC, or the like. The electrostatic chuck electrode 26 may be, for example, a planar electrode. The ceramic substrate 20 may incorporate one layer of the electrostatic chuck electrode 26, or two or more layers spaced apart.

The electrostatic chuck electrode 26 is connected to an external DC power source via a power supply member (not shown). A low-pass filter may be disposed on the way of the power supply member. The power supply member is electrically insulated from the bonding layer 40 and the base plate 30. When a DC voltage is applied to the electrostatic chuck electrode 26, the wafer W is attracted and fixed to the upper surface 21a by electrostatic attraction force, and when the application of the DC voltage is stopped, the wafer W is released from the attraction and fixation to the upper surface 21a. The ceramic substrate 20 may incorporate an RF electrode for generating plasma instead of or in addition to the electrostatic chuck electrode 26.

Further, the ceramic substrate 20 also has a plurality of heater electrodes 27 that are zoned. The heater electrodes 27 are arranged, for example, such that a plurality of zones are formed in a plane direction parallel to the upper surface 21a of the ceramic substrate 20. The output of each of the plurality of heater electrodes 27 that are zoned can be controlled. This allows the upper surface 21a of the ceramic substrate 20 to be divided into a plurality of zones, enabling temperature control for each zone, thereby improving the ability to control the temperature distribution of the wafer.

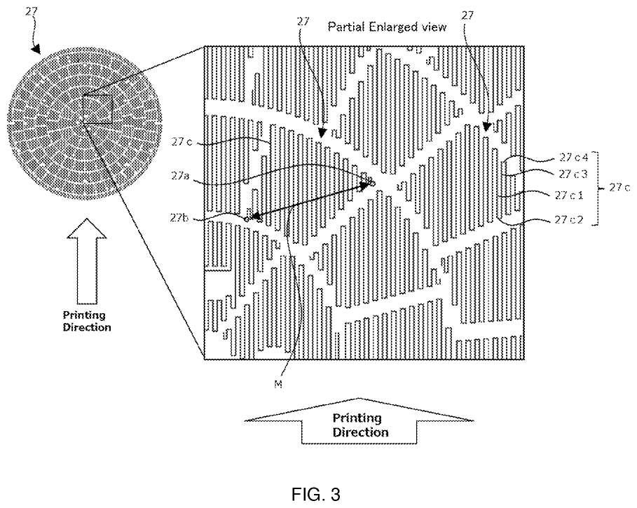

The heater electrode 27 may be provided only in the central portion 20a of the ceramic substrate 20, but the heater electrode 27 may also be provided in the outer peripheral portion 20b of the ceramic substrate 20 (i.e., below the focus ring 78). In order to improve the performance of controlling the temperature distribution of the wafer, the ceramic substrate 20 preferably has 10 or more heater electrodes 27 in total, more preferably 50 or more, and even more preferably 100 or more.
FIG. 3 shows a schematic planar structure of a plurality of heater electrodes 27 when viewed in a virtual plan view. Each of the plurality of the heater electrodes 27 has a heater line 27c extending in a direction parallel to the upper surface 21a of the ceramic substrate 20. Each of the plurality of heater electrodes 27 has a first connection portion 27a (+side) which is the connection point with the second via 62 and a second connection portion 27b (−side) which is the connection point with the fourth via 64, and the two are electrically connected via a heater line 27c. In one embodiment, the heater line 27c extends linearly in a direction parallel to the upper surface 21a of the ceramic substrate 20 in a single stroke manner.

The average area of the cross section (average cross-sectional area) A₁ orthogonal to the direction of current flow of the heater electrode 27 (the extending direction of the heater line 27c) is not limited. However, a smaller cross-sectional area has the advantage that the resistance is high and the required heat generation can be achieved with a small amount of current, but if the cross-sectional area is too small, variations in printing thickness have a significant impact on the amount of heat generation. For these reasons, the average cross-sectional area is preferably 0.0001 to 0.1 mm², more preferably 0.0005 to 0.01 mm², and even more preferably 0.001 to 0.005 mm². As used herein, the average cross-sectional area A₁ of the heater electrode 27 is measured by the following procedure. The heater electrode 27 to be measured is cut at four length positions of 20%, 40%, 60%, and 80% with respect to the total length of the heater line 27c to cut out cross sections orthogonal to the direction of current flow of the heater electrode 27, and the area of each cross section is measured. Then, the average value of the cross-sectional areas at these four positions is calculated as the average cross-sectional area A₁.

The heater electrodes 27 are generally formed by screen printing. If there is a difference between the printing direction and the extending direction of the heater lines 27c that make up the heater electrodes 27, the printing thickness is likely to vary. If the printing thickness varies, it becomes difficult to make the heater electrode 27 generate heat uniformly. For this reason, it is preferable to determine the extending direction of the heater lines such that the printing direction and the extending direction of the heater lines can be aligned as closely as possible.

Specifically, when the plurality of heater electrodes 27 are viewed in a virtual plan view, it is preferable that 90% or more of the length of the heater line 27c of at least one heater electrode of the plurality of heater electrodes 27 be composed of a plurality of straight line portions within an angle range of 20° or less. More preferably, 90% or more of the length of the heater line 27c of at least one heater electrode of the plurality of heater electrodes 27 be composed of a plurality of straight line portions within an angle range of 10° or less. Even more preferably, 90% or more of the length of the heater line 27c of at least one heater electrode of the plurality of heater electrodes 27 be composed of a plurality of straight line portions within an angle range of 5° or less.

Furthermore, when the plurality of heater electrodes 27 are viewed in a virtual plan view, it is preferable that 90% or more of the total length of all the heater lines 27c of the plurality of heater electrodes 27 be composed of a plurality of straight line portions within an angle range of 20° or less. It is more preferable that 90% or more of the total length of all the heater lines 27c of the plurality of heater electrodes 27 be composed of a plurality of straight line portions within an angle range of 10° or less. It is even more preferable that 90% or more of the total length of all the heater lines 27c of the plurality of heater electrodes 27 be composed of a plurality of straight line portions within an angle range of 5° or less.

In one embodiment, when the plurality of heater electrodes 27 are viewed in a virtual plan view, the heater line 27c of at least one, preferably at least half, more preferably at least 90% of the plurality of heater electrodes 27, and even more preferably all of the plurality of heater electrodes 27 extend linearly from one end to the other such that the following portions repeatedly appears:
a first straight portion 27c1 extending in a first direction;
a second straight portion 27c2 connected to the first straight portion 27c1 and extending in a second direction perpendicular to the first direction;
a third straight portion 27c3 connected to the second straight portion 27c2 and extending in the opposite direction to the first direction;
a fourth straight portion 27c4 connected to the third straight portion 27c3 and extending in a second direction perpendicular to the first direction; and
the first straight portion 27c1 connected to the fourth straight portion 27c4 and extending in the first direction.

By extending the heater line 27c as described above, the heater line 27c moves away from one end to the other end in the second direction. Therefore, the first connection portion 27a (+side) and the second connection portion 27b (−side) can be arranged apart from each other without being adjacent to each other. While the first connection portion 27a (+side) and the second connection portion 27b (−side) are connected to the vias, the heat generated at these connection portions to the vias may be weak. If areas with low heat generation are close to each other, they will become cool spots, so it is preferable to provide some space between them to improve heat uniformity.

Specifically, the lower limit of the straight-line distance M from one end to the other end of the heater line 27c is preferably 5 mm or more, more preferably 10 mm or more, and even more preferably 20 mm or more. Although the upper limit of the straight-line distance M from one end to the other end of the heater line 27c is not particularly set, in order to arrange many heater zones, it is preferably 50 mm or less, more preferably 40 mm or less, and even more preferably 30 mm or less. Therefore, the straight-line distance M from one end to the other end of the heater line 27c is, for example, preferably 5 mm or more and 50 mm or less, more preferably 10 mm or more and 40 mm or less, and even more preferably 20 mm or more and 30 mm or less.

From the viewpoint of uniform heating, it is preferable that the distance between the via connection portions (27a, 27b) of adjacent heater electrodes 27 be also large. For example, the shortest distance between the via connection portions of adjacent heater electrodes 27 is preferably 3 mm or more, more preferably 5 mm or more, and even more preferably 10 mm or more. Of the total number of pairs of adjacent heater electrodes 27, it is preferable that 30% or more of the pairs satisfy the above-mentioned shortest distance condition, more preferably 50% or more of the pairs satisfy the above-mentioned shortest distance condition, and even more preferably 70% or more of the pairs satisfy the above-mentioned shortest distance condition. In addition, in order to align the extending directions of the heater lines 27c of the heater electrodes 27, some pairs of adjacent heater electrodes 27 may not satisfy the above-mentioned condition of the shortest distance. For example, the ratio of the number of pairs that satisfy the above-mentioned shortest distance condition to the total number of pairs of adjacent heater electrodes 27 is 30 to 95%, typically 50 to 90%, and more typically 70 to 90%.

The heater electrode 27 can be made of, for example, a mixed material of metal and ceramic. The metal may contain, for example, one or more elements selected from W, Mo, and Ru. It is preferable that the thermal expansion coefficient of the ceramic material constituting the ceramic substrate 20 is close to that of the ceramic material. As the ceramic, it is preferable to use the same material as the ceramic substrate 20 (for example, alumina, aluminum nitride). By forming the heater electrode 27 from such a mixed material, the risk of cracks occurring between the heater electrode 27 and the ceramic substrate 20 due to the difference in thermal expansion between them can be reduced.

The planar shape of the jumper electrode 29a provides the advantage of suppressing heat generation in the jumper electrode compared to when the jumper electrode is linear. That the jumper electrode 29a is planar means that the jumper electrode 29a extends in a plane direction parallel to the upper surface 21a of the ceramic substrate 20, and can typically be flat (for example, foil-like), but may also have an uneven shape such as a mesh-like shape. The thickness of each planar jumper electrode 29a can be, for example, 10 to 100 μm, and typically 20 to 50 μm.

The area of one planar jumper electrode 29a (excluding opening portion(s)) as viewed in a plan view is preferably 450 mm² or more, more preferably 700 mm or more, and even more preferably 1400 mm² or more, for the reason of suppressing heat generation. In addition, the area of one planar jumper electrode 29a (excluding opening portion(s)) as viewed in a plan view is preferably 15,000 mm² or less, more preferably 7,000 mm² or less, and even more preferably 4,000 mm² or less, for the reason of simplifying electrode zoning. Therefore, the area of one planar jumper electrode 29a (excluding opening(s)) as viewed in a plan view is, for example, preferably 450 to 15,000 mm², more preferably 700 to 7,000 mm², and even more preferably 1,400 to 4,000 mm².

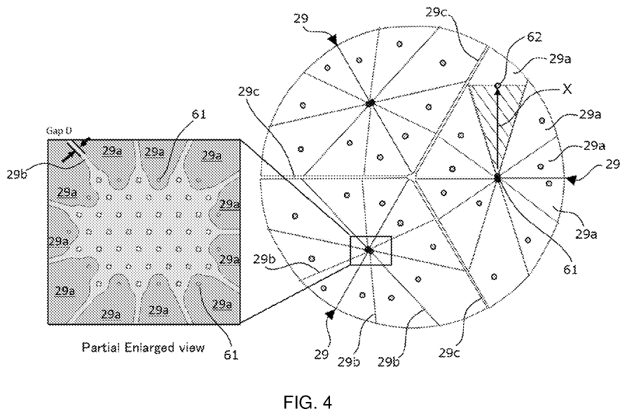

Referring to FIG. 4, the average area of the cross section (average cross-sectional area) A₂ of the planar jumper electrode 29a orthogonal to the direction of current flow (the direction from the connection point with the first via 61 to the connection point with the second via 62 in a plan view) X is not limited, but is preferably larger in order to suppress heat generation. On the other hand, if the cross-sectional area is too large, the cost of the electrode material will increase, so it is preferably 0.1 to 3.0 mm², more preferably 0.2 to 1.5 mm², and even more preferably 0.4 to 0.8 mm². As used herein, the average cross-sectional area A₂ of the planar jumper electrode 29a is measured by the following procedure. When the planar jumper electrode 29a to be measured is viewed in a plan view, the average width in the direction orthogonal to the direction of current flow X is calculated in the area from the center of the connection point with the first via 61 to the center of the connection point with the second via 62 (see the hatched area in FIG. 4). Also, the thickness of the planar jumper electrode 29a in that region is measured. The thickness is measured by the following procedure. The planar jumper electrode 29a is cut along a cutting line orthogonal to the direction of current flow X, which bisects the distance from the center of the connection point with the first via 61 to the center of the connection point with the second via 62, and the thickness at the center of the width direction of the obtained cross section is taken as the measurement value. Then the average width in the direction orthogonal to the direction of current flow X is multiplied by the thickness of the planar jumper electrode 29a to obtain the average cross-sectional area A₂.

It is preferable that each of the plurality of heater electrodes 27 satisfies the following Formula 1 with the planar jumper electrode 29a electrically connected to the heater electrode 27:

A₂/A₁≥10 . . . Formula 1

(In which, A₁ represents an average cross-sectional area of the heater electrode 27 in a cross section orthogonal to the direction of current flow, and A₂ represents an average cross-sectional area of the planar jumper electrode 29a in a cross section orthogonal to the direction of current flow.)

By satisfying the above relationship, the electrical resistance of the planar jumper electrode 29a can be made relatively small with respect to the heater electrode 27. Therefore, there are advantages in that it becomes easier to control the potential difference generated in the heater electrode 27, temperature controllability can be improved, and heat generation from the planar jumper electrode 29a can be suppressed. From the viewpoint of improving temperature controllability, it is more preferable to satisfy A₂/A₁≥50, and even more preferable to satisfy A₂/A₁≥100.

On the other hand, from the viewpoint of reducing the amount of electrode material used and reducing manufacturing costs, it is preferable to satisfy 30,000≥A₂/A₁, it is more preferable to satisfy 3,000≥A2/A₁, and it is even more preferable to satisfy 800≥A₂/A₁.

Therefore, from the viewpoint of satisfying both temperature controllability and manufacturing costs, it is preferable to satisfy 30,000≥A₂/A₁≥10, it is more preferable to satisfy 3,000≥A₂/A₁≥50, and it is even more preferable to satisfy 800≥A₂/A₁≥100.

In each jumper electrode layer 29 of one or more jumper electrode layers 29 connected to a plurality of terminals 52a constituting the terminal-dense portion 52 in each single section 55, adjacent planar jumper electrodes 29a can be electrically isolated from each other by a linearly extending insulator 29b (for example, ceramic). The insulator 29b may be made of the ceramic (alumina and/or aluminum nitride, or the like) that constitutes the ceramic substrate 20, for example. In addition, the insulator 29b is not limited to the above, and the insulator 29b may be made of a ceramic material different from that of the ceramic substrate 20.

For each of the plurality of planar jumper electrodes 29a constituting at least one jumper electrode layer 29, preferably at least half of the jumper electrode layers 29, and more preferably all of the jumper electrode layers among the one or more jumper electrode layers 29 connected to the plurality of terminals 52a constituting the terminal-dense portion 52 in each single section 55,, the gap D between adjacent planar jumper electrodes 29a in the same layer (that is, the line width of the linearly extending insulators 29b) is preferably 0.1 mm or more, more preferably 0.2 mm or more, and even more preferably 0.3 mm or more (see FIG. 4). This reduces the risk of malfunction caused by electrical connection between adjacent planar jumper electrodes 29a. On the other hand, from the viewpoint of reducing the risk of generating more heat by narrowing the width of the planar jumper electrode 29a, the gap D is preferably 2 mm or less, more preferably 1.5 mm or less, and even more preferably 1 mm or less. Therefore, for each of the plurality of planar jumper electrodes 29a constituting at least one jumper electrode layer 29, preferably at least half of the jumper electrode layers 29, and more preferably all of the jumper electrode layers among the one or more jumper electrode layers 29 connected to the plurality of terminals constituting the terminal-dense portion 52 in each single section 55,, the gap D between adjacent planar jumper electrodes 29a in the same layer is preferably 0.1 to 2 mm, more preferably 0.2 to 1.5 mm, and even more preferably 0.3 to 1 mm.

The linearly extending insulator 29b is arranged such that it does not linearly overlap any of the straight portions of the heater line 27c of at least one heater electrode 27 of the plurality of the heater electrodes 27 in the vertical direction. Since the linearly extending insulator 29b and the heater lines 27c do not linearly overlap in the vertical direction, the occurrence of cracks when the ceramic substrate 20 shrinks during firing in its production process is suppressed. The linearly extending insulator 29b is preferably arranged such that it does not linearly overlap any of the straight portions of the heater lines 27c of at least half the number of the heater electrodes 27 of the plurality of the heater electrodes 27 in the vertical direction. The linearly extending insulator 29b is more preferably arranged such that it does not linearly overlap any of the straight portions of all the heater lines 27c of the plurality of heater electrodes 27 in the vertical direction.

As used herein, that the linearly extending insulator 29b does not linearly overlap any of the straight portions of the heater line 27c in the vertical direction means that, when the heater electrode 27 is viewed virtually from above, the extending direction of the linearly extending insulator 29b does not coincide with the extending direction of any of the straight portions of the heater line 27c, or even if it does coincide, it is shifted horizontally, so that no linear overlap occurs in the vertical direction. When the heater electrode 27 is viewed virtually from above, it is acceptable for the two to intersect, resulting in partial point-like overlapping in the vertical direction.

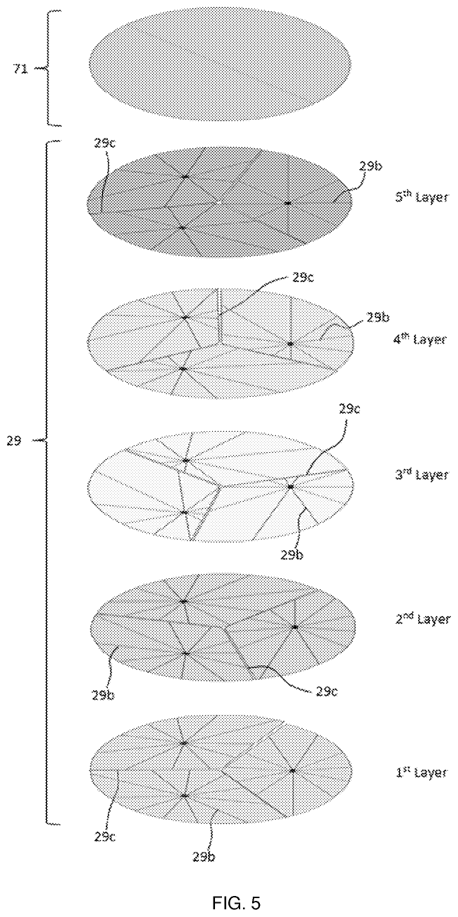

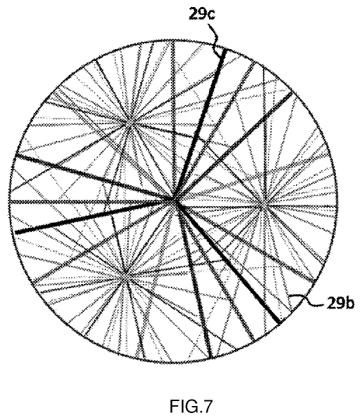

Furthermore, it is preferable that the linearly extending insulator 29b does not linearly overlap any of the linearly extending insulators 29b in different jumper electrode layers 29 in the vertical direction. FIG. 7 shows a schematic view of a plurality of planar jumper electrodes 29a constituting the five jumper electrode layers 29 shown in FIG. 5 as viewed virtually from above. This further reduces the risk of cracks occurring in the ceramic substrate 20.

Referring to FIG. 2, each of the plurality of terminals 52a arranged in the terminal-dense portion 52 is electrically connected to a predetermined planar jumper electrode 29a through a first via 61 extending in the vertical direction. One terminal 52a may be electrically connected to a plurality of planar jumper electrodes 29a, or a plurality of terminals 52a may be electrically connected to one planar jumper electrode 29a. In a preferred embodiment, each of the terminals 52a is connected to one predetermined planar jumper electrode 29a.

Each terminal 52a can be fixed to the ceramic substrate 20 by, for example, brazing. In addition, each terminal 52a of the terminal-dense portion 52 can be connected to a power supply member (not shown) that is connected to a heater power source. There are no particular limitations on the shape of each terminal 52a, but it may be, for example, a rigid rod extending in the vertical direction or a flexible wire.

The average cross-sectional area A₃ of the cross section orthogonal to the direction of current flow of the first via 61 is not limited, but is preferably 0.002 to 0.2 mm², more preferably 0.008 to 0.1 mm², and even more preferably 0.016 to 0.05 mm², because if the cross-sectional area is too small, the resistance increases and heat is generated, and if the cross-sectional area is too large, the insulating distance between the electrodes cannot be secured. As used herein, the average cross-sectional area A₃ of the first via 61 is measured by the following procedure. The first via 61 to be measured is cut at three length positions: 20%, 50%, and 80% with respect to the total length in the direction of current flow (vertical direction) to cut out cross sections orthogonal to the direction of current flow of the first via 61, and the area of each cross section is measured. Then, the average value of the cross-sectional areas at these three positions is calculated as the average cross-sectional area A₃.

It is preferable that each of the plurality of heater electrodes 27 satisfies the following Formula 2 with the first via 61 electrically connected to the heater electrode 27 through the predetermined planar jumper electrode 29a:

A₃/A₁≥5 . . . Formula 2

(In which, A₁ represents an average cross-sectional area of the heater electrode 27 in a cross section orthogonal to the direction of current flow, and A₃ represents an average cross-sectional area of the first via 61 in a cross section orthogonal to the direction of current flow.)

By satisfying the above relationship, the electrical resistance of the first via 61 can be made relatively small with respect to the heater electrode 27. Therefore, there are advantages in that it becomes easier to control the potential difference generated in the heater electrode 27, temperature controllability can be improved, and heat generation from the first via 61 can be suppressed. From the viewpoint of improving temperature controllability, it is more preferable to satisfy A₃/A₁≥7, and it is even more preferable to satisfy A₃/A₁≥10.

On the other hand, from the viewpoint of reducing the risk of defects due to insufficient insulation distance between the first vias 61, it is preferable to satisfy 2000≥A₃/A₁, it is more preferable to satisfy 200≥A₃/A₁, and it is even more preferable to satisfy 50≥A₃/A₁.

Therefore, from the viewpoint of satisfying both temperature controllability and mass productivity, it is preferable to satisfy 2000≥A₃/A₁≥5, it is more preferable to satisfy 200≥A₃/A₁≥7, and it is even more preferable to satisfy 50≥A₃/A₁≥10.

Further, each of the plurality of planar jumper electrodes 29a is electrically connected to the first connection portion 27a of the predetermined heater electrode 27 selected from the plurality of heater electrodes 27 through the second via 62 extending in the vertical direction.

The average cross-sectional area A₄ of the cross section orthogonal to the direction of current flow of the second via 62 is not limited, but is preferably 0.002 to 1 mm², more preferably 0.008 to 0.3 mm², and even more preferably 0.016 to 0.07 mm², because if the cross-sectional area is too small, the resistance increases and heat is generated, and if the cross-sectional area is too large, the risk of breakage due to the difference in thermal expansion between the electrode and the ceramic increases. As used herein, the average cross-sectional area A₄ of the second via 62 is measured by the following procedure. The second via 62 to be measured is cut at three length positions of 20%, 50%, and 80% with respect to the total length in the direction of current flow (vertical direction) to cut out cross sections orthogonal to the direction of current flow of the second via 62, and the area of each cross section is measured. Then, the average value of the cross-sectional areas at these three positions is calculated as the average cross-sectional area A₄.

It is preferable that each of the heater electrodes 27 satisfies the following Formula 3 with the second via 62 electrically connected to the heater electrode 27:

A₄/A₁≥5 . . . Formula 3

(In which, A₁ represents an average cross-sectional area of the heater electrode 27 in a cross section orthogonal to the direction of current flow, and A₄ represents an average cross-sectional area of the second via 62 in a cross section orthogonal to the direction of current flow.)

By satisfying the above relationship, the electrical resistance of the second via 62 can be made relatively small with respect to the heater electrode 27. Therefore, there are advantages in that it becomes easier to control the potential difference generated in the heater electrode 27, temperature controllability can be improved, and heat generation from the second via 62 can Be suppressed. from the viewpoint of improving temperature controllability, it Is more preferable to satisfy A₄/A₁≥7, and it is even more preferable to satisfy A₄/A₁≥10.

On the other hand, from the viewpoint of reducing the risk of breakage due to the difference in thermal expansion between the electrode material of the second via 62 and the ceramic of the ceramic substrate 20, it is preferable to satisfy 10,000≥A₄/A₁, it is more preferable to satisfy 600≥A₄/A₁, and it is even more preferable to satisfy 70≥A₄/A₁.

Therefore, from the viewpoint of satisfying both temperature controllability and mass productivity, it is preferable to satisfy 10,000≥A₄/A₁≥5, it is more preferable to satisfy 600≥A₄/A₁≥7, and it is even more preferable to satisfy 70≥A₄/A₁≥10.

The second connection portion 27b of each of the plurality of heater electrodes 27 can be electrically connected to a common terminal 72 through a common jumper 71. The common terminal 72 can be connected to a grounding (earthing) wire, for example. In addition, the common terminal 72 may also be connected to a heater power supply. The common jumper 71 can be electrically connected to the common terminal 72 through a third via 63 extending in the vertical direction.

The second connection portion 27b can be electrically connected to the common jumper 71 through the fourth via 64 extending in the vertical direction. The average cross-sectional area A₅ of the cross section orthogonal to the direction of current flow (vertical direction) of the fourth via 64 is not limited, but is preferably 0.002 to 1 mm², more preferably 0.008 to 0.3 mm², and even more preferably 0.016 to 0.07 mm², because if the cross-sectional area is too small, the resistance increases and heat is generated, and if the cross-sectional area is too large, the risk of breakage due to the difference in thermal expansion between the electrode and the ceramic increases. As used herein, the average cross-sectional area A₅ of the fourth via 64 is measured by the following procedure. The fourth via 64 to be measured is cut at three length positions of 20%, 50%, and 80% with respect to the total length in the direction of current flow (vertical direction) to cut out cross sections orthogonal to the direction of current flow of the fourth via 64, and the area of each cross section is measured. Then, the average value of the cross-sectional areas at these three positions is calculated as the average cross-sectional area A₅.

It is preferable that each of the heater electrodes 27 satisfies the following Formula 4 with the fourth via 64 electrically connected to the heater electrode 27:

A₅/A₁≥5 . . . Formula 4

(In which, A₁ represents the average cross-sectional area of the heater electrode 27 in a cross section orthogonal to the direction of current flow, and A₅ represents the average cross-sectional area of the fourth via 64 in a cross section orthogonal to the direction of current flow.)

By satisfying the above relationship, the electrical resistance of the fourth via 64 can be made relatively small with respect to the heater electrode 27. Therefore, there are advantages in that it becomes easier to control the potential difference generated in the heater electrode 27, the temperature controllability can be improved, and heat generation from the fourth via 64 can be suppressed. From the viewpoint of improving temperature controllability, it is more preferable to satisfy A₅/A₁≥7, and it is even more preferable to satisfy A₅/A₁≥1.

On the other hand, from the viewpoint of reducing the risk of breakage due to the difference in thermal expansion between the electrode of the fourth via 64 and the ceramic, it is preferable to satisfy 10,000≥A₅/A₁, it is more preferable to satisfy 600≥A₅/A₁, and it is even more preferable to satisfy 70≥A₅/A₁.

Therefore, from the viewpoint of satisfying both temperature controllability and mass productivity, it is preferable to satisfy 10,000≥A₅/A₁≥5, it is more preferable to satisfy 600≥A₅/A₁≥7, and it is even more preferable to satisfy 70≥A₅/A₁≥10.

In the illustrated embodiment, the common terminal 72 is inserted into the ceramic substrate 20 and can be fixed by brazing. This configuration can increase the bonding strength of the common terminal 72. However, the common terminal 72 only needs to be electrically connected to the common jumper 71, and does not need to be inserted inside the ceramic substrate 20. For example, the common terminal 72 may be fixed to the lower surface 23 of the ceramic substrate 20 or to the bottom surface of the recess 35 provided on the lower surface 23 by brazing.

The common jumper 71 can be formed at a different height from the jumper electrode layer 29 and the heater electrode 27 through the insulator 28. In the embodiment shown in FIG. 1, the common jumper 71 is formed between the jumper electrode layer 29 and the heater electrode 27. The position of the common jumper 71 is not limited to this, and it may be provided at a position above the heater electrode 27, for example.

One common jumper 71 can be electrically connected to all or some of the plurality of terminals of one or more terminal-dense portions 52. In one embodiment, all of the plurality of terminals in one terminal-dense portion 52 may be electrically connected to one common jumper 71. In another embodiment, among the plurality of terminals in one terminal-dense portion 52, some terminals may be electrically connected to one common jumper 71, and the other terminals may be electrically connected to another common jumper 71. As the number of the common jumpers 71 increases, there arises an advantage that the current is dispersed and the less heat is generated. However, as the number of common terminals 72 increases, there arises a disadvantage that costs are increased and the wiring becomes more complicated. Therefore, the member for a semiconductor manufacturing equipment 10 preferably has 1 to 5 common jumpers 71 in total, and more preferably has 1 to 3 common jumpers 71 in total.

In a preferred embodiment, the common jumper 71 is planar. The planar shape of the common jumper 71 provides the advantage of suppressing heat generation compared to when the common jumper 71 is linear. That the common jumper 71 is planar means that the common jumper 71 extends in a plane direction parallel to the upper surface 21a of the ceramic substrate 20, and can typically be flat (for example, foil-like), but may also be an uneven shape such as a mesh-like shape. The thickness of the common jumper 71 can be, for example, 10 to 100 μm, and typically 30 to 80 μm. In addition, the area of one common jumper 71 (excluding opening portions(s)) as viewed in a plan view is preferably 3,500 mm² or more, more preferably 7,000 mm² or more, and even more preferably 14,000 mm² or more, for the reason of suppressing heat generation. In addition, the area of one common jumper 71 (excluding opening portions(s)) as viewed in a plan view is preferably 70,000 mm² or less, and more preferably 40,000 mm² or less, for the reason of simplifying electrode zoning. Therefore, the area of one common jumper 71 (excluding opening portions(s)) as viewed in a plan view is, for example, preferably 3,500 to 70,000 mm², more preferably 7,000 to 40,000 mm², and even more preferably 14,000 to 40,000 mm².

One common terminal 72 may be provided, or a plurality of common terminals 72 may be provided for one terminal-dense portion 52. However, from the viewpoint of suppressing heat generation caused by current concentration in the common terminal, it is preferable to provide a plurality of common terminals 72 for one terminal-dense portion 52.

In the illustrated embodiment, the common terminal 72 is provided in a recess 35 provided on the lower surface 23 of the ceramic substrate 20. The recess 35 may not be provided. The common terminal 72 can be bonded to the ceramic substrate 20 by brazing or soldering, for example. There are no particular limitations on the common terminal 72, but it may be, for example, a rigid rod extending in the vertical direction or a flexible cable.

The planar jumper electrode 29a and the common jumper 71 can contain one or more elements selected from W, Mo, and Ru, and can be formed, for example, from a mixed material of one or more elements selected from W, Mo, and Ru with ceramic.
The first via 61, the second via 62, the third via 63, and the fourth via 64 can contain one or more elements selected from W, Mo, and Ru, and can be formed, for example, from a mixed material of one or more elements selected from W, Mo, and Ru with ceramic.
The terminal 52a and the common terminal 72 can be formed from a material such as Mo or Kovar (Fe—Ni—Co alloy).

The third via 63 is prone to heat generation because current supplied through each terminal 52a is concentrated therein. Therefore, in order to suppress excessive heat generation of the third via 63, it is preferable that the average cross-sectional area A₆ of the cross section of the third via 63 orthogonal to the direction of current flow is larger than the average cross-sectional area A₁ of any of the heater electrodes 27 electrically connected to the third via 63. The ratio of the average cross-sectional area A₆ of the third vias 63 to the average cross-sectional area A₁ of the heater electrodes 27 may be set appropriately taking into consideration the current flowing through the third vias 63, and may be, for example, 50≤A₆/A₁≤2000, and typically 100≤A₆/A₁≤1000. Increasing the average cross-sectional area A₆ of t₆e third via also contributes to improving the temperature controllability by the heater electrodes.

As used herein, the average cross-sectional area A₆ of the third via 63 is measured by the following procedure. The third via 63 to be measured is cut at three length positions of 20%, 50%, and 80% with respect to the total length in the direction of current flow (vertical direction) to cut out cross sections orthogonal to the direction of current flow of the third via 63, and the area of each cross section is measured. Then, the average value of the cross-sectional areas at these three positions is calculated as the average cross-sectional area A₆.

The terminal-dense portion 52 is a portion in which a plurality of terminals 52a are arranged within a single section 55. In the embodiment shown in FIG. 1, only one terminal-dense portion 52 is shown. Depending on the wiring that supplies power to the terminals, the ceramic substrate 20 may be provided with a plurality of terminal-dense portions 52, that is, a plurality of single sections 55. There is no particular limit to the number of terminals 52a arranged in the terminal-dense portion 52 within a single section 55, but for example, it can be 10 to 100, and typically 20 to 70. In the embodiment shown in FIG. 1, the terminal-dense portion 52 is provided in a recess 34 provided on the lower surface 23 of the ceramic substrate 20, and a single section 55 is partitioned by the recess 34. The recess 34 may not be provided.

Referring to FIG. 2, one or more jumper electrode layers 29 electrically connect the plurality of heater electrodes 27 to the respective terminals 52a of the terminal-dense portion 52, and are stacked in the vertical direction with insulators 28 interposed therebetween. The distance between vertically adjacent jumper electrode layers 29 (equal to the thickness T of the insulator 28 between the layers) is preferably 0.02 to 1 mm, more preferably 0.02 to 0.5 mm, and even more preferably 0.02 to 0.2 mm, in order to strike a balance between ensuring insulation between the vertically adjacent jumper electrode layers 29 and reducing the manufacturing cost by thinning the ceramic substrate 20.

As the number of jumper electrode layers 29 increases, the number of laminations increases, which increases the manufacturing cost. Therefore, it is desirable to have a small number of jumper electrode layers 29. In order to reduce the number of jumper electrode layers 29, it is preferable that each jumper electrode layer 29 has a plurality of planar jumper electrodes 29a. Therefore, each jumper electrode layer 29 can be composed of a plurality of planar jumper electrodes 29a electrically separated by the linearly extending insulators 29b.

While a larger number of planar jumper electrodes 29a in the same jumper electrode layer 29 helps to reduce the number of jumper electrode layers 29, it is better not to have an excessively large number of planar jumper electrodes 29a because a narrower width of each planar jumper electrode 29a will increase heat generation. Therefore, among the one or more jumper electrode layers 29 electrically connected to the plurality of terminals 52a constituting the terminal-dense portion 52 in each single section 55, at least one jumper electrode layer 29, preferably at least half of the jumper electrode layers 29, and more preferably all of the jumper electrode layers 29 are preferably each composed of 5 to 15 planar jumper electrodes 29a, and more preferably composed of 8 to 12 planar jumper electrodes 29a.

FIG. 5 shows example shapes of a plurality of planar jumper electrodes 29a that constitute each of the first to fifth jumper electrode layers 29 and example shapes of common jumpers when the upper surface 21a, which is the wafer placement surface of the ceramic substrate 20, is circular, the number of terminal-dense portions 52 is three, and the number of jumper electrode layers 29 is five. In the embodiment shown in FIG. 5, the planar shape of one jumper electrode layer 29 electrically connected to the plurality of terminals 52a in one terminal-dense portion 52 is approximately a sector with the center of the circle formed by the upper surface 21a as the reference for the central angle. In the embodiment shown in FIG. 5, three jumper electrode layers 29 are arranged at the same height position on each of the first to fifth layers. The three jumper electrode layers 29 are electrically connected to the corresponding terminal-dense portion 52. The three jumper electrode layers 29 at the same height (the same layer number) are arranged so as to correspond as a whole to the planar shape (circular in FIG. 5) of the upper surface 21a, which is the wafer placement surface.

In the embodiment shown in FIG. 5, the three jumper electrode layers 29 at the same height (the same layer number) are all approximately sector-shaped with substantially the same central angle (specifically, 120°), and are electrically isolated from one another via insulators 29c (for example, ceramic) extending linearly along the radius. It is preferable that the linearly extending insulators 29c that electrically separate adjacent jumper electrode layers 29 do not linearly overlap in the vertical direction with any of the linearly extending insulators 29c in different jumper electrode layers 29. FIG. 7 shows a schematic view of a plurality of planar jumper electrodes constituting the five jumper electrode layers illustrated in FIG. 5 as viewed virtually from above. This reduces the risk of cracks occurring in the ceramic substrate 20. The line width of the linearly extending insulators 29c (equal to the distance between adjacent jumper electrode layers 29) is not limited to, but may be, for example, 0.3 to 2 mm, and typically 0.3 to 1 mm.

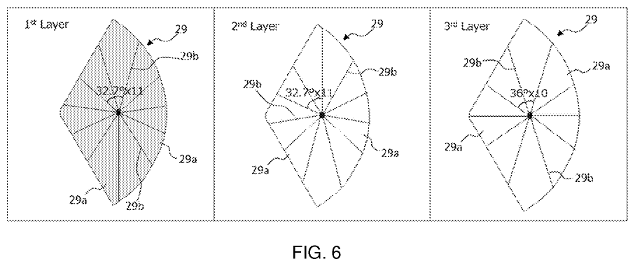

FIG. 6 shows a schematic plan view of each of the first to third jumper electrode layers 29 as an example. Among the plurality of jumper electrode layers 29 electrically connected to the plurality of terminals 52a constituting the terminal-dense portion 52 in each single section 55, it is preferable that each of the plurality of planar jumper electrodes 29a constituting at least one jumper electrode layer 29, preferably at least half of the jumper electrode layers 29, and more preferably all of the jumper electrode layers 29 have a planar shape composed of two line segments adjacent at a constant angle with the position of the first via 61 as the vertex. Current tends to concentrate near the first via 61 extending in the vertical direction from the terminal-dense portion 52, and heat is likely to be generated. Therefore, by spreading the planar jumper electrodes 29a at equal intervals, there arises an advantage that heat can be easily dispersed.

Referring to FIG. 6, in the first and second jumper electrode layers 29, each of the eleven planar jumper electrodes 29a has a planar shape composed of two line segments adjacent at an angle of 32.7° (=360°/11). In the third jumper electrode layer 29, ten planar jumper electrodes 29a each have a planar shape composed of two line segments adjacent at an angle of 36° (=360°/10).

From the viewpoint of reducing manufacturing costs, the total number A of the jumper electrode layers 29 is preferably 20 or less, more preferably 10 or less, and even more preferably 5 or less. On the other hand, from the viewpoint of increasing the number of heater electrodes to increase the number of zones and thereby improving the performance of controlling the temperature distribution of the wafer, the total number A of the jumper electrode layers 29 is preferably 2 or more, more preferably 3 or more, and even more preferably 4 or more. Therefore, the total number A of the jumper electrode layers 29 is, for example, preferably 2 to 20, more preferably 3 to 10, and even more preferably 4 to 5.

### 1-2. Base Plate

The base plate 30 may be, for example, disk-shaped. In one embodiment, the base plate 30 comprises a central portion 30a having a circular upper surface 31a in a plan view, and a flange portion 30b having an annular upper surface 31b on the outer periphery of the central portion 30a in a plan view. The thickness of the central portion 30a can be set to, for example, 5 to 30 mm. The flange portion 30b can be used to clamp or bolt the member for a semiconductor manufacturing equipment 10 to a mounting plate disposed on the lower surface 33 side. In addition, a ring heater (not shown) can also be placed on the flange portion 30b. In this case, the ring heater can be bolted to the installation plate.

The base plate 30 can be made of, for example, a metal material or a composite material of metal and ceramic. Examples of the metal material include Al, Ti, Mo, and alloys thereof. Examples of the composite material of metal and ceramic include metal matrix composites (MMC) and ceramic matrix composites (CMC). Specific examples of the composite materials include materials containing Si, SiC, and Ti (also known as SiSiCTi), materials in which porous SiC is impregnated with Al and/or Si, and composite materials of Al₂O₃ and TiC, and the like. A material in which a porous SiC body is impregnated with Al is called AlSiC, and a material in which a porous SiC body is impregnated with Si is called SiSiC. It is preferable to select a material for the base plate 30 that has a thermal expansion coefficient close to that of the ceramic that constitutes the ceramic substrate 20. For example, when the ceramic substrate 20 is made of alumina, the base plate 30 is preferably made of SiSiCTi or AlSiC, which have a thermal expansion coefficient close to that of alumina.

The base plate 30 can be used as an RF electrode by connecting it To an Rf Power Source via a Power Supply Terminal (not Shown). a High Pass filter (HPF) may be placed between the base plate 30 and the RF power source.

A refrigerant flow path 32 through which a refrigerant circulates may be formed inside the base plate 30. The refrigerant flowing through the refrigerant flow path 32 is preferably liquid and is preferably electrically insulating. Examples of electrically insulating liquid include fluorine-based inert liquids. The refrigerant flow path 32 can be formed, for example, in a single stroke manner from one end (inlet) to the other end (outlet) across the entire base plate 30 in a plan view. One end and the other end of the refrigerant flow path 32 are connected to a supply port and a recovery port, respectively, of an external refrigerant device (not shown). The refrigerant supplied to one end of the refrigerant flow path 32 from the supply port of the external refrigerant device passes through the refrigerant flow path 32, returns from the other end of the refrigerant flow path 32 to the recovery port of the external refrigerant device, and after its temperature is adjusted, is supplied again from the supply port to the one end of the refrigerant flow path 32.

### 1-3. Bonding Layer

The bonding layer 40 bonds the lower surface 23 of the ceramic substrate 20 and the upper surface 31a of the base plate 30 together. The bonding layer 40 may be configured as a metal layer made of, for example, solder or metal brazing material. The bonding layer 40 is formed, for example, by TCB (Thermal Compression Bonding). TCB is a known method in which a metal bonding material is sandwiched between two members to be bonded, and the two members are pressure-bonded while being heated to a temperature below the solidus temperature of the metal bonding material. The bonding layer 40 is not limited to a metal layer. For example, a resin bonding layer may be used instead of a metal layer. The resin bonding layer can be made of, for example, a cured product of a silicone resin-based adhesive, an epoxy resin-based adhesive, an acrylic resin-based adhesive, or a urethane resin-based adhesive.

The bonding layer 40 and the base plate 30 may have a through hole at a location corresponding to the terminal-dense portion 52 in order to facilitate connection of the power supply member to the terminals 52a of the terminal-dense portion 52. Further, the bonding layer 40 and the base plate 30 may have a through hole at a location corresponding to the common terminal 72 in order to make it easier to connect the earth wire 73 to the common terminal 72.

### 1-4. Others

The side surface of the outer peripheral portion 20b of the ceramic substrate 20, the outer periphery of the bonding layer 40, the side surface of the base plate 30, and the upper surface 31b of the flange portion 30b can be covered with an insulating film 42. The insulating film 42 may be, for example, a thermally sprayed film of alumina or yttria.

In the above-described embodiment, the member for a semiconductor manufacturing equipment 10 may have a plurality of holes that penetrate the member for a semiconductor manufacturing equipment 10 in the vertical direction. Such holes include a plurality of gas holes opening in the upper surface 21a and lift pin holes for inserting lift pins that move the wafer W up and down relative to the upper surface 21a. A plurality of gas holes can be provided at appropriate positions when the upper surface 21a is viewed from above. The gas holes are supplied with a thermally conductive gas such as He gas. Normally, the gas holes can be provided so as to have an opening in areas free from the seal band or the small protrusions on the upper surface 21a where the above-mentioned seal band and small protrusions are provided,. When the thermal conduction gas is supplied to the gas holes, the thermal conduction gas fills the space on the back side of the wafer W placed on the upper surface 21a. A plug having a gas flow path may be embedded in the gas holes. A plurality of lift pin holes can be provided at equal intervals along a concentric circle on the upper surface 21a when the upper surface 21a is viewed in a plan view.

### 2. How to Use Member for Semiconductor Manufacturing Equipment

Next, an example of how to use the member for a semiconductor manufacturing equipment 10 will be described. The common terminal 72 of the member for a semiconductor manufacturing equipment 10 is connected to the ground via an earth wire 73. Further, each terminal 52a of the terminal-dense portion 52 is connected to a heater power supply via a power supply member (not shown). In this state, when voltage is applied from the heater power supply, current flows in the following order: each terminal 52a in the terminal-dense portion 52→first via 61→jumper electrode layer 29→second via 62→each heater electrode 27→fourth via 64→common jumper 71→third via 63→common terminal 72, causing each heater electrode 27 to generate heat. By changing the voltage applied to each terminal 52a, it is possible to change the amount of heat generated by the plurality of heater electrodes 27 that are zoned. This makes it possible to realize a desired heat distribution on the ceramic substrate 20, and therefore, for example, it is possible to control the temperature distribution of the wafer W attracted and fixed to the upper surface 21a of the ceramic substrate 20.

A method for chucking the wafer W will now be described. First, with the member for a semiconductor manufacturing equipment 10 installed in a chamber (not shown), the wafer w is placed on the upper surface 21a of the ceramic substrate 20. Then, the chamber is depressurized using a vacuum pump to adjust it to a predetermined vacuum level, and a voltage is applied to the electrostatic chuck electrode 26 to generate an electrostatic chucking force, thereby attracting and fixing the wafer W to the upper surface 21a of the ceramic substrate 20.

A method for processing the wafer W will be described. The chamber is filled with a reactive gas atmosphere at a predetermined pressure (for example, several tens to several hundreds of Pa), and the plurality of heater electrodes 27 that are zoned are controlled such that the temperature distribution of the wafer W attracted and fixed to the upper surface 21a of the ceramic substrate 20 is in a desired state. Then, a high-frequency voltage such as an RF voltage is applied between an upper electrode (not shown) provided on the ceiling of the chamber and the base plate 30 of the member for a semiconductor manufacturing equipment 10 to generate plasma. The surface of the wafer W is processed by the generated plasma.

### 3. Method for Producing Member for Semiconductor Manufacturing Equipment

Next, a method for producing the member for a semiconductor manufacturing equipment 10 will be described by way of example.

First, a method for producing the ceramic substrate 20 will be described. A plurality of disk-shaped green sheets that will become the base of the ceramic substrate 20 are prepared. The green sheets can be produced by, for example, tape casting. Grooves are formed on the lower surface of the first green sheet from the bottom layer at the locations where the recesses 34 and 35 are to be provided. In addition, a through hole is formed in the green sheet at a position corresponding to the first via 61, and the through hole is filled with conductive paste to form a paste-filled portion. Further, if necessary, a through hole is also formed at the position where the common terminal 72 is inserted. Next, a conductive paste is printed on the upper surface of the green sheet so as to obtain the same pattern as the first jumper electrode layer 29, thereby forming a first jumper precursor.

For the second and subsequent green sheets (Nth sheet) from the bottom layer onwards, a through hole is formed at positions corresponding to the first via 61, the second via 62, the third via 63, and the fourth via 64 as necessary, and conductive paste is filled into the through hole to form a paste-filled portion. Further, if necessary, a through hole is formed at the position where the common terminal 72 is to be inserted. Next, a conductive paste is printed on the upper surface of the green sheet in the same pattern as the jumper electrode layer 29, the common jumper 71 or the heater electrode 27 required depending on the order from the bottom layer to form a jumper precursor or heater electrode precursor. The top green sheet can be used without any processing.

As a method for printing the conductive paste, screen printing can be suitably used. Further, when the conductive paste for the heater electrode 27 is screen-printed, the printing direction is preferably as close as possible to the direction in which the plurality of straight line portions of the heater electrode 27 extend (for example, within 20°, preferably within 10°), and it is more preferable to match them. This increases the proportion in which the extending direction of the heater line 27c constituting the heater electrode 27 coincides with the printing direction, thereby making it possible to suppress variations in the printing thickness. In the member for a semiconductor manufacturing equipment 10 according to the above-described embodiment, a high proportion of the heater lines 27c extend in the same direction, which is advantageous because it is easy to align the extending direction of the heater lines 27c with the printing direction.

After the green sheets have been subjected to predetermined processing from the bottom layer to the top layer, they are stacked in order from the bottom to the top to form a laminate. This laminate is fired to obtain the ceramic substrate 20. In addition, the electrostatic chuck electrode 26 and vias (not shown) connected to the electrostatic chuck electrode 26 can be formed inside the ceramic substrate 20 by a conventional method.

In addition to the ceramic substrate 20, a base plate 30 and a metal bonding material are prepared. The base plate 30 has a refrigerant flow path 32. Furthermore, the base plate 30 and the metal bonding material may have through holes for accessing the recesses 34 and 35 in the ceramic substrate 20. The base plate 30 having the refrigerant flow path 32 can be manufactured, for example, by joining multiple aluminum or MMC plate members, on which grooves and holes corresponding to the refrigerant flow path 32 have been formed by machining, using methods such as electron beam, welding, diffusion bonding, or TCB. The through holes can be formed by machining.

Next, a resin or metal bonding material is sandwiched between the lower surface 23 of the ceramic substrate 20 and the upper surface 31a of the base plate 30 to form a laminate. Then, the laminate is pressed and bonded at a temperature below the solidus temperature of the metal bonding material (for example, from a temperature 20 °C lower than the solidus temperature to the solidus temperature), and then returned to room temperature (TCB). As a result, the metal bonding material becomes a bonding layer 40, and a bonded body in which the ceramic substrate 20 and the base plate 30 are bonded together by the bonding layer 40 is obtained. It is preferable to use a metal bonding material with a thickness of about 100 μm (for example, 80 to 240 μm).

Thereafter, the plurality of terminals 52a constituting the terminal-dense portion 52 are connected to the corresponding first vias 61 by a method such as brazing, respectively. In addition, the common terminal 72 is connected to the third via 63 by a method such as brazing. Thereafter, the semiconductor manufacturing equipment member 10 is completed by appropriately undergoing processes such as adjusting the overall shape.

### DESCRIPTION OF REFERENCE NUMERALS

10: Member for semiconductor manufacturing equipment
20: Ceramic substrate
20a: Central portion
20b: Outer peripheral portion
21a: Upper surface
21b: Upper surface
23: Lower surface
26: Electrostatic chuck electrode
27: Heater electrode
27a: First connection portion
27b: Second connection portion
27c: Heater line
27c1: First straight portion
27c2: Second straight portion
27c3: Third straight portion
27c4: Fourth straight portion
28: Insulator
29: Jumper electrode layer
29a: Jumper electrode
29b: Insulator
29c: Insulator
30: Base plate
30a: Central portion
30b: Flange portion
31a: Upper surface
31b: Upper surface
32: Refrigerant flow path
33: Lower surface
34: Recess
35: Recess
40: Bonding layer
42: Insulating film
52: Terminal-dense portion
52a: Terminal
55: Single section
61: First via
62: Second via
63: Third via
64: Fourth via
71: Common jumper
72: Common terminal
73: Earth wire
78: Focus ring
W: Wafer

1. A member for a semiconductor manufacturing equipment comprising a ceramic substrate, the ceramic substrate comprising:
an upper surface on which a wafer is to be placed;
a terminal-dense portion in which a plurality of terminals are arranged within a single section;
a plurality of heater electrodes that are zoned; and
one or more jumper electrode layers disposed between and electrically connected to the plurality of heater electrodes and each terminal of the terminal-dense portion;
wherein each of the plurality of heater electrodes comprises a heater line extending in a direction parallel to the upper surface of the ceramic substrate, and when the plurality of heater electrodes are viewed in a virtual plan view, 90% or more of a length of the heater line of at least one heater electrode of the plurality of heater electrodes is composed of a plurality of straight line portions within an angle range of 20° or less; and
wherein each of the jumper electrode layers is composed of a plurality of planar jumper electrodes electrically isolated by a linearly extending insulator, and the linearly extending insulator does not linearly overlap any of the plurality of straight line portions of the heater line of the at least one heater electrode in a vertical direction.

2. The member for a semiconductor manufacturing equipment according to claim 1, wherein when the plurality of heater electrodes are viewed in a virtual plan view, 90% or more of a total length of all the heater lines of the plurality of heater electrodes is composed of a plurality of straight line portions within an angle range of 20° or less, and the linearly extending insulator does not linearly overlap any of the plurality of straight line portions of any of the heater lines in the vertical direction.

3. The member for a semiconductor manufacturing equipment according to claim 1, wherein each of the plurality of heater electrodes satisfies the following Formula 1 with the planar jumper electrode electrically connected to the heater electrode:
A₂/A₁≥10 . . . Formula 1
(In which, A₁ represents an average cross-sectional area of the heater electrode in a cross section orthogonal to a direction of current flow, and A₂ represents an average cross-sectional area of the planar jumper electrode in a cross section orthogonal to the direction of current flow.)

4. The member for a semiconductor manufacturing equipment according to claim 1, wherein each of the plurality of terminals arranged in the terminal-dense portion is electrically connected to a predetermined planar jumper electrode through a first via extending in the vertical direction; and
each of the plurality of heater electrodes satisfies the following Formula 2 with the first via electrically connected to the heater electrode through the predetermined planar jumper electrode:
A₃/A₁≥5 . . . Formula 2
(In which, A₁ represents an average cross-sectional area of the heater electrode in a cross section orthogonal to a direction of current flow, and A₃ represents an average cross-sectional area of the first via in a cross section orthogonal to the direction of current flow.)

5. The member for a semiconductor manufacturing equipment according to claim 1, wherein each of the plurality of planar jumper electrodes is electrically connected to a predetermined heater electrode selected from the plurality of heater electrodes through a second via extending in the vertical direction; and
each of the heater electrodes satisfies the following Formula 3 with the second via electrically connected to the heater electrode:
A₄/A₁≥5 . . . Formula 3
(In which, A₁ represents an average cross-sectional area of the heater electrode in a cross section orthogonal to a direction of current flow, and A₄ represents an average cross-sectional area of the second via in a cross section orthogonal to the direction of current flow.)

6. The member for a semiconductor manufacturing equipment according to claim 1, wherein the ceramic substrate comprises 10 or more heater electrodes that are zoned.

7. The member for a semiconductor manufacturing equipment according to claim 1, wherein the ceramic substrate further comprises an electrode for electrostatic attraction.

8. The member for a semiconductor manufacturing equipment according to claim 1, wherein the ceramic substrate comprises a ceramic containing 90% by mass or more of alumina.

9. The member for a semiconductor manufacturing equipment according to claim 1, wherein the heater electrode comprises one or more elements selected from W, Mo, and Ru.

10. The member for a semiconductor manufacturing equipment according to claim 4, wherein the first via comprises one or more elements selected from W, Mo, and Ru.

11. The member for a semiconductor manufacturing equipment according to claim 5, wherein the second via comprises one or more elements selected from W, Mo, and Ru.

12. The member for a semiconductor manufacturing equipment according to claim 1, wherein when the plurality of heater electrodes are viewed in a virtual plan view, the heater line of at least one of the plurality of heater electrodes extends linearly from one end to the other end such that the following portions repeatedly appear:
a first straight portion extending in a first direction;
a second straight portion connected to the first straight portion and extending in a second direction perpendicular to the first direction;
a third straight portion connected to the second straight portion and extending in a direction opposite to the first direction;
a fourth straight portion connected to the third straight portion and extending in the second direction perpendicular to the first direction; and
the first straight portion connected to the fourth straight portion and extending in the first direction.

13. The member for a semiconductor manufacturing equipment according to claim 12, wherein a straight-line distance from the one end to the other end of the heater line is 5 mm or more.
